(19) United States
(12) Patent Application Publication
(10) Pub. No.: US 2025/0107276 A1
(43) Pub. Date: Mar. 27, 2025

(54) SEMICONDUCTOR DEVICE HAVING AN ISOLATION STRUCTURE AND METHODS OF PRODUCING THE SEMICONDUCTOR DEVICE

(71) Applicant: Infineon Technologies Austria AG, Villach (AT)

(72) Inventors: Annett Winzer, Dresden (DE); Lars Müller-Meskamp, Dresden (DE); Tom Peterhänsel, Dresden (DE)

(21) Appl. No.: 18/893,133

(22) Filed: Sep. 23, 2024

(30) Foreign Application Priority Data
Sep. 27, 2023 (DE) 102023209447.9

(51) Int. Cl. H01L 33/00; H01L 23/64; H01L 29/06; H01L 33/38

(52) U.S. Cl. CPC H10H 20/062; H01L 23/642; H10D 62/114; H10D 62/115; H10H 20/8312

(57) ABSTRACT

A semiconductor device includes: a silicon layer having a thickness in a range of 2 μm to 200 μm between a frontside and a backside of the silicon layer; a first device region and a second device region laterally isolated from one another in the silicon layer by an isolation structure that extends from the frontside to the backside of the silicon layer; a first insulation layer on the frontside of the silicon layer; a first patterned metallization on the first insulation layer; a second insulation layer on the backside of the silicon layer; and a second patterned metallization on the second insulation layer. The first patterned metallization provides lateral electrical routing along the frontside of the silicon layer. The second patterned metallization provides lateral electrical routing along the backside of the silicon layer. Additional embodiments of semiconductor devices and methods of producing the semiconductor devices are also described.

### BACKGROUND

For integrated high voltage (e.g., 20V or higher) devices such as a diode, an LDMOS (laterally diffused metal-oxide-semiconductor), etc., the device must be optimized for the intended application. For example, ruggedness, low on resistance, high breakdown voltage, etc. may require optimization. To optimize parameters such as ruggedness, resistance, and breakdown voltage, the potential and fields inside the device must be controlled for all operating conditions. Existing solutions include field guiding elements, such as field plates above silicon, graded implant schemes, p/n compensation structures and the like. All of these solutions help produce an efficient integrated high voltage device, but further efficiency gains can be realized by improving the device design.

### SUMMARY

According to an embodiment of a semiconductor device, the semiconductor device comprises: a silicon layer having a thickness in a range of 2 μm to 200 μm between a frontside and a backside of the silicon layer; a first device region and a second device region laterally isolated from one another in the silicon layer by an isolation structure that extends from the frontside to the backside of the silicon layer; a first insulation layer on the frontside of the silicon layer; a first patterned metallization on the first insulation layer; a second insulation layer on the backside of the silicon layer; and a second patterned metallization on the second insulation layer, wherein the first patterned metallization provides lateral electrical routing along the frontside of the silicon layer, wherein the second patterned metallization provides lateral electrical routing along the backside of the silicon layer.

According to an embodiment of a method of producing a semiconductor device, the method comprises: forming a silicon layer having a thickness in a range of 2 μm to 200 μm between a frontside and a backside of the silicon layer; forming a first device region and a second device region that are laterally isolated from one another in the silicon layer by an isolation structure that extends from the frontside to the backside of the silicon layer; forming a first insulation layer on the frontside of the silicon layer; forming a first patterned metallization on the first insulation layer; forming a second insulation layer on the backside of the silicon layer; and forming a second patterned metallization on the second insulation layer, wherein the first patterned metallization provides lateral electrical routing along the frontside of the silicon layer, wherein the second patterned metallization provides lateral electrical routing along the backside of the silicon layer.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of part of a semiconductor device having a frontside patterned metallization and a backside patterned metallization, according to an embodiment.

FIG. 2 illustrates a cross-sectional view of part of the semiconductor device during a blanket backside implantation process, according to an embodiment.

FIG. 3 illustrates a cross-sectional view of part of the semiconductor device during a masked backside implantation process, according to an embodiment.

FIGS. 4A through 4C illustrate cross-sectional views of part of the semiconductor device during part of the manufacturing process, according to an embodiment.

FIGS. 5A and 5B illustrate cross-sectional views of part of the semiconductor device during part of the manufacturing process, according to an embodiment.

FIGS. 6A through 6C illustrate cross-sectional views of part of the semiconductor device during formation of the backside patterned metallization, according to an embodiment.

FIGS. 7 through 9 illustrate respective cross-sectional views of part of the semiconductor device, according to additional embodiments.

FIG. 10A illustrates a top plan view and FIG. 10B illustrates a corresponding cross-sectional view along the line labelled A-A′ in FIG. 10A of part of the semiconductor device, according to an embodiment.

FIG. 11A illustrates a top plan view and FIG. 11B illustrates a corresponding cross-sectional view along the line labelled B-B′ in FIG. 11A of part of the semiconductor device, according to an embodiment.

FIG. 12A illustrates a top plan view and FIG. 12B illustrates a corresponding cross-sectional view along the line labelled C-C′ in FIG. 12A of part of the semiconductor device, according to an embodiment.

FIG. 13 illustrates a partial top plan view of the silicon layer of the semiconductor device, according to another embodiment.

### DETAILED DESCRIPTION

The embodiments described provide a semiconductor device and methods of producing the semiconductor device. The semiconductor device includes a silicon layer having a thickness in a range of 2 μm to 200 μm between front and back sides of the silicon layer. Two or more device regions are laterally isolated from one another in the silicon layer by an isolation structure that extends from the frontside to the backside of the silicon layer. A patterned metallization is disposed at both sides of the silicon layer. The frontside patterned metallization provides lateral electrical routing along the frontside of the silicon layer. The backside patterned metallization provides lateral electrical routing along the backside of the silicon layer. The isolation structure and/or a through silicon via may be used to provide vertical electrical routing between the frontside patterned metallization and the backside patterned metallization.

The semiconductor device described herein enables power and/or signal routing along both the front and back sides of the device, and enables back-gating for frontside devices. The semiconductor device also enables vertical devices with power and/or signal routing via the backside, and selective contacts to, e.g., a lead frame at the bottom of the device for electrical and thermal connection. With the patterned backside metallization and by using a conductive trench/plug, a bias voltage (back-gating) can be capacitively applied to a lateral high voltage (e.g., 20V or higher) or power device (e.g., 1A or higher) at the frontside surface. The back bias can enhance device functionality, e.g., by lowering leakage, increasing on-current for forward bias, enabling better transient operation, reducing cross-coupling from other devices, etc. Moreover, the controlled backside bias also allows to stack high voltage devices for higher voltages, without reengineering the device. In the case of SOI (silicon-on-insulator) technology, capacitive coupling from the frontside to the backside enables transmission of information via the backside. Capacitance or leakage sensing may be enabled for in-situ detection of backside oxide failure.

Described next, with reference to the figures, are embodiments of the semiconductor device and related methods of manufacturing.

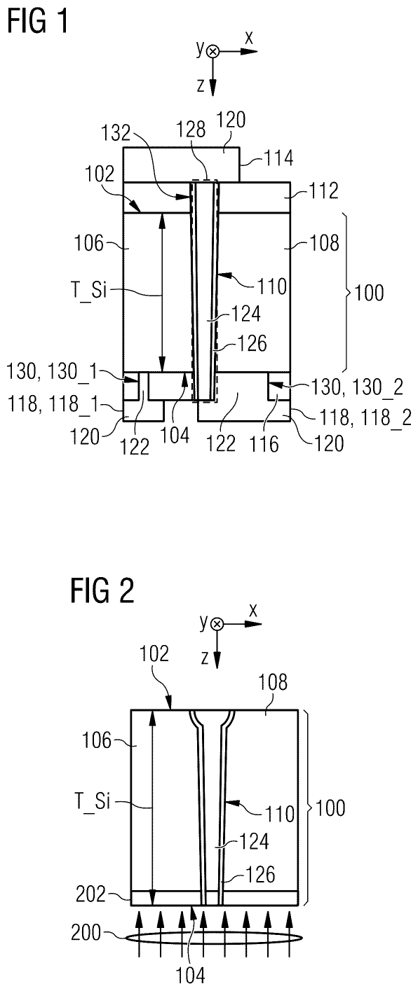

FIG. 1 illustrates a cross-sectional view of part of a semiconductor device, according to an embodiment. The semiconductor device includes a silicon layer 100 having a thickness T_Si in the depth direction (z direction in FIG. 1) in a range of 2 μm (microns) to 200 μm between a frontside 102 and a backside 104 of the silicon layer 100. In one embodiment, the silicon layer 100 is realized by forming one or more devices such as a power diode(s), high voltage transistor(s), a gate driver for a power transistor, etc. in a bulk silicon wafer or in one or more epitaxial layers grown on a bulk silicon wafer, and then grinding the backside of the bulk silicon wafer to the final thickness T_Si. The resulting silicon layer 100 is thicker (e.g., T_Si=2 μm to 200 μm) than typical SOI device layers which usually have a thickness in the nanometer (nm) range. The silicon layer 100 instead may be a standard SOI device layer formed by SIMOX (separation by implantation of oxygen, wafer bonding, etc. and having a thickness T_Si of less than 10 μm. The silicon layer 100 may be doped n-type or p-type.

A first device region 106 and a second device region 108 are laterally isolated from one another in the silicon layer 100 by an isolation structure 110 that extends from the frontside 102 to the backside 104 of the silicon layer 100. Depending on the target application, the same type of device or different types of devices may be formed in the first and second device regions 106, 108, example embodiments of which are described in more detail later. The semiconductor device may include more than two device regions 106, 108 laterally isolated from one another in the silicon layer 100 by an isolation structure 110.

The semiconductor device also includes a first (frontside) insulation layer 112 on the frontside 102 of the silicon layer 100 a first (frontside) patterned metallization 114 on the frontside insulation layer 112. A second (backside) insulation layer 116 is on the backside 104 of the silicon layer 100 and a second (backside) patterned metallization 118 is on the backside insulation layer 116. The frontside and backside insulation layers 112, 116 may be deposited oxides, for example. However, any suitable type of dielectric material (e.g., SiO₂, SiN₄, etc.) may be used as the frontside and backside insulation layers 112, 116. The frontside and backside metallizations 114, 118 may include a single metallic layer or a stack of metallic layers 120. The frontside and backside metallizations 114, 118 may include one or more vias 122 that extend through the respective insulation layer 112, 116 and connect to a metallic layer(s) 120, e.g., in the case of a Cu damascene structure.

The frontside patterned metallization 114 provides lateral electrical routing along the frontside 102 of the silicon layer 100. For example, the frontside patterned metallization 114 may laterally route power and/or signals between the device regions 106, 108 at the frontside 102 of the silicon layer 100. The backside patterned metallization 118 similarly provides lateral electrical routing along the backside 104 of the silicon layer 100. For example, the backside patterned metallization 118 may laterally route power and/or signals to one or more of the device regions 106, 108 at the backside 104 of the silicon layer 100. Separately or in combination, the backside patterned metallization 118 may apply a back bias to one or more of the device regions 106, 108 at the backside 104 of the silicon layer 100. Separately or in combination, the backside patterned metallization 118 may provide capacitive coupling to one or more of the device regions 106, 108 at the backside 104 of the silicon layer 100.

In one embodiment, the isolation structure 110 that extends from the frontside 102 to the backside 104 of the silicon layer 100 provides vertical electrical routing between the frontside patterned metallization 114 and the backside patterned metallization 118. For example, the isolation structure 110 may include an electrically conductive material 124 laterally separated from the silicon layer 100 by a dielectric material and/or a pn junction 126. In this example, the electrically conductive material 124 provides vertical electrical routing between the frontside patterned metallization 114 and the backside patterned metallization 118. The electrically conductive material 124 is made of an electrically conductive material such as polysilicon and/or a metal or metal stack.

In the case of a dielectric material as the isolation material 126, the dielectric material may line each sidewall of a trench which is then filled with the electrically conductive material that forms the electrically conductive material 124. The dielectric material may be SiOx, SiN, HfOx, AlxOy (e.g., Al₂O₃), TEOS (tetraethoxysilane), etc., or a layer stack of two or more of these or similar dielectric materials. The trench is etched into the silicon layer 100 before the silicon layer 100 is thinned to the target/final thickness T_Si. The dielectric material lines the sidewalls and bottom of the trench. Later, the silicon layer 100 is thinned from the backside 104 until the target thickness T_Si is reached. The thinning process may expose the electrically conductive material that forms the electrically conductive material 124 at the bottom of the trench, enabling vertical electrical routing between the frontside 102 and the backside 104 of the silicon layer 100. In other cases, the electrically conductive material 124 may remain covered by the dielectric material at the bottom of the trench.

In the case of a pn junction as the isolation material 126, the pn junction is a boundary or interface between two types of semiconductor materials inside the silicon layer 100. For example, the silicon layer 100 may be p-type or n-type near the isolation structure 110 and an intervening region of the opposite conductivity type may directly adjoin the electrically conductive material 124. The region of the opposite conductivity type directly adjoining the electrically conductive material 124 may be formed by ion implantation or out-diffusion of n-type dopants in a p-type substrate or p-type dopants in an n-type substrate.

In another embodiment, a through-silicon via (TSV) 128 provides vertical electrical routing between the frontside patterned metallization 114 and the backside patterned metallization 118. The TSV 128 is illustrated as a dashed rectangle in FIG. 1 to provide an unobstructed view of the isolation structure 110. The TSV 128 is formed after the silicon layer 100 is thinned to the target/final thickness T_Si, by deep etching through the thinned silicon layer 100, lining the via with an insulating liner, opening the liner at the bottom, filling the lined via with a metal or metal alloy, and connecting the metal or metal alloy to the adjacent patterned metallization 114 at the frontside 102 of the silicon layer 100 and to the adjacent patterned metallization 118 at the backside 104 of the silicon layer 100. The electrically conductive material 124 and the corresponding isolation material 126 are shown in FIG. 1 as extending from a bottom side of the frontside patterned metallization 114 to a top side of the backside patterned metallization 118. This is the case for the TSV 128, which is formed after the frontside and backside insulation layers 112, 116 are formed.

For the isolation structure 110, at least the isolation material 126 terminates at the frontside 102 and the backside 104 of the silicon layer 100 since the isolation structure 110 is formed before the silicon layer 100 is thinned to the final thickness T_Si. The electrically conductive material 124 may or may not be covered by the corresponding isolation material 126 at the backside 104 of the silicon layer 100, depending on the design and function of the isolation structure 110. If the isolation structure 110 is provided only for lateral isolation of adjacent device regions 106, 108, then the electrically conductive material 124 may be covered by the isolation material 126 at the backside 104 of the silicon layer 100. However, if the isolation structure 110 is also used for vertical electrical routing between the frontside patterned metallization 114 and the backside patterned metallization 118, then the electrically conductive material 124 is exposed from (i.e. uncovered by) the isolation material 126 at the backside 104 of the silicon layer 100.

Depending on the type of material used to form the electrically conductive material 124 in the isolation structure 110, the TSV 128 may have a lower electrical resistance than the isolation structure 110. Still, the isolation structure 110 may be used to provide vertical electrical routing between the frontside 102 and backside 104 of the silicon layer 100 if the electrically conductive material 124 is exposed at the bottom of the trench that delimits the isolation structure 110. In either case, the vertical routing capability provided by the isolation structure 110 and/or the TSV 128 can route power via the patterned metallizations 114, 118 at the front and back sides 102, 104 of the silicon layer 100, thereby enabling vertical devices, power/signal routing vat the backside 104, selective contact to a substrate such as a lead frame at the backside 104 for electrical and/or thermal connection, etc.

The number of isolation structures 110 included in the semiconductor device depends on the number of device regions 106, 108 that require lateral isolation. The semiconductor device may include one or more TSVs 128 or no TSVs 128, depending on whether vertical electrical routing is required between the frontside patterned metallization 114 and the backside patterned metallization 118 and whether the isolation structure(s) 110 is used to provide the vertical routing.

As shown in FIG. 1, the backside patterned metallization 118 may contact the silicon layer 100 at the backside 104 through openings 130 in the backside insulation layer 116. For example, the backside patterned metallization 118 may contact the first and second device regions 106, 108 at the backside 104 of the silicon layer 100, or just one of the device regions 106, 108 at the backside 104. One or more islands or segments of the backside patterned metallization 118 that contacts the silicon layer 100 at the backside 104 may be vertically electrically connected to the frontside patterned metallization 114 by the isolation structure 110 or the TSV 128.

For example, in FIG. 1, the backside patterned metallization 118 includes a first section 118_1 that contacts the silicon layer 100 at the backside 104 through a first opening 130_1 in the backside insulation layer 116 and a second section 118_2 that contacts the electrically conductive region 124 of the isolation structure 110 or of the TSV 128 through a second opening 130_2 in the backside insulation layer 116. Also in FIG. 1, the frontside patterned metallization 114 may contact the electrically conductive region 124 of the isolation structure 110 or of the TSV 128 through an opening 132 in the frontside insulation layer 112.

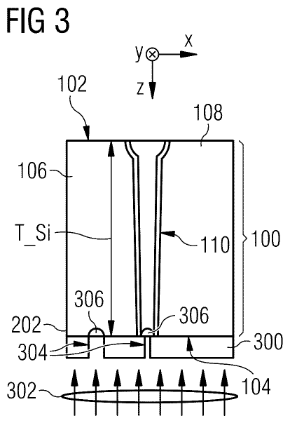

FIG. 2 illustrates a cross-sectional view of part of the semiconductor device during a blanket backside implantation process, according to an embodiment. In FIG. 2, a dopant species 200 is blanket implanted into the backside 104 of the silicon layer 100 after the silicon layer 110 is formed to have a thickness T_Si in a range of 10 μm to 200 μm but before forming both the backside insulation layer 116 and the backside patterned metallization 118.

After an annealing process that activates the implanted dopant species 200, the silicon layer 100 includes a doped contact region 202 that will adjoin each part of the backside patterned metallization 118 that contacts the silicon layer 100 at the backside 104. The bottom part of the electrically conductive material 124 in the isolation structure 110 also may be doped, if the electrically conductive material 124 is exposed at the bottom of the trench that defines the isolation structure 110.

Each doped contact region 202 has a higher doping concentration than material of the silicon layer 100 that adjoins the doped contact region 202. For a p+ doped contact region 202, the dopant species may be boron, aluminum, indium, etc. For an n+ doped contact region 202, the dopant species may be phosphorous, arsenic, antimony, etc.

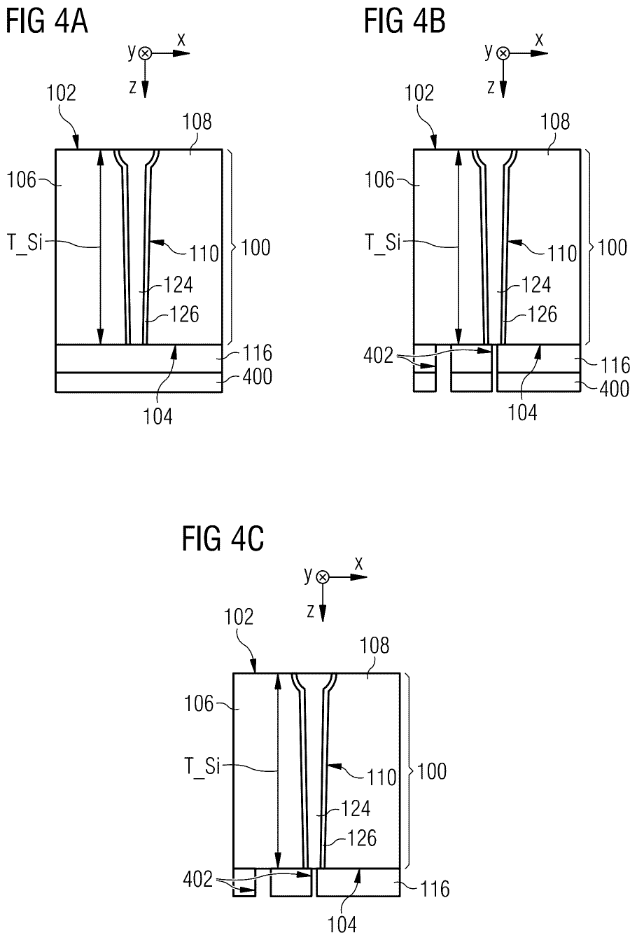

FIG. 3 illustrates a cross-sectional view of part of the semiconductor device during a masked backside implantation process, according to an embodiment. In FIG. 3, a resist layer 300 is formed on the backside 104 of the silicon layer 100 and a dopant species 302 is implanted into the backside 104 of the silicon layer 100 through openings 304 in the resist layer 300 after the silicon layer 100 is formed to have a thickness T_Si in a range of 10 μm to 200 μm but before forming both the backside insulation layer 116 and the backside patterned metallization 118.

After an annealing process that activates the implanted dopant species 302, the silicon layer 100 includes a doped contact region 306 that will adjoin each part of the backside patterned metallization 118 that contacts the silicon layer 100 at the backside 104. The bottom part of the electrically conductive material 124 in the isolation structure 110 also may be doped, if the electrically conductive material 124 is exposed at the bottom of the trench that defines the isolation structure 110.

Each doped contact region 306 has a higher doping concentration than material of the silicon layer 100 that adjoins the doped contact region 306. For a p+ doped contact region 306, the dopant species may be boron, aluminum, indium, etc. For an n+ doped contact region 306, the dopant species may be phosphorous, arsenic, antimony, etc.

Contact regions of both doping type (n and p) can be formed at different locations in the silicon layer 100. For example, a structured n-type contact may be formed, followed by a structured p-type implant, followed by a subsequent cleaning step and then metal deposition to form the backside patterned metallization 118.

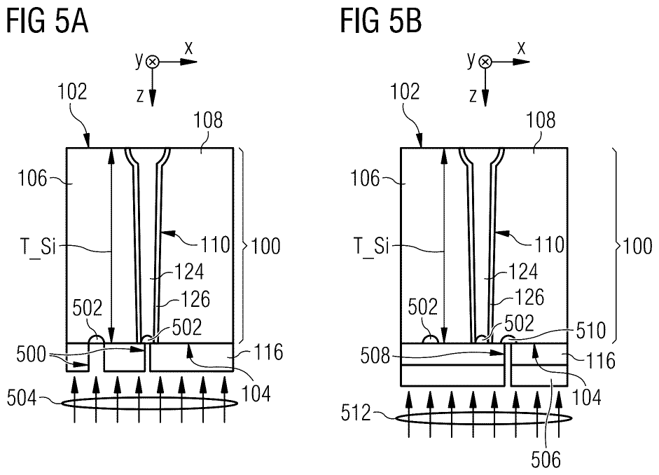

FIGS. 4A through 4C illustrate cross-sectional views of part of the semiconductor device during part of the manufacturing process, according to an embodiment. In FIG. 4A, a resist layer 400 is formed on the backside insulation layer 116 after the silicon layer 100 is formed to have a thickness T_Si in a range of 10 μm to 200 μm but before forming the backside patterned metallization 118. In FIG. 4B, openings 402 are formed in the resist layer 400 and the backside insulation layer 116 to expose regions of the silicon layer 100 at the backside 104. Doped regions such as highly doped contact regions may be formed by implanting a dopant species (not shown in FIGS. 4A through 4C, but see FIGS. 2 and 3) into the exposed part of the backside 104 of the silicon layer 100 through the openings 402 in the resist layer 400 and the backside insulation layer 116. In FIG. 4C, the resist layer 400 is removed from the backside insulation layer 116.

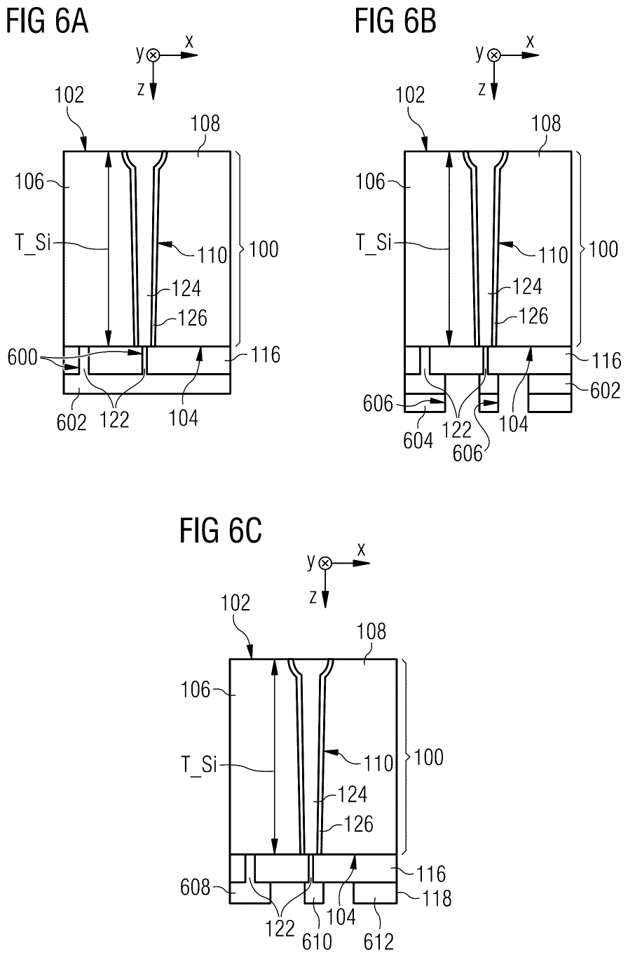

FIGS. 5A and 5B illustrate cross-sectional views of part of the semiconductor device during part of the manufacturing process, according to an embodiment. In FIG. 5A, openings 500 are formed in the backside insulation layer 116 to expose regions of the silicon layer 100 at the backside 104. Doped regions 502 such as highly doped contact regions may be formed by implanting a dopant species 504 into the exposed part of the backside 104 of the silicon layer 100 through the openings 500 in the backside insulation layer 116. The type of dopant species 500 depends on whether n-type or p-type regions 502 are being formed. In FIG. 5B, a resist layer 506 is formed on the backside insulation layer 116 after the first backside implantation 504. One or more openings 508 is then formed in the resist layer 506 and the backside insulation layer 116 to expose at least one other region of the silicon layer 100 at the backside 104. A doped region 510 such as highly doped contact region is formed by implanting another dopant species 512 into each exposed part of the backside 104 of the silicon layer 100 through each opening 508 in the resist layer 506 and the backside insulation layer 116. Each doped region 510 shown in FIG. 5B may have the opposite conductivity type and/or different dopant concentration than the doped regions 502 shown in FIG. 5A.

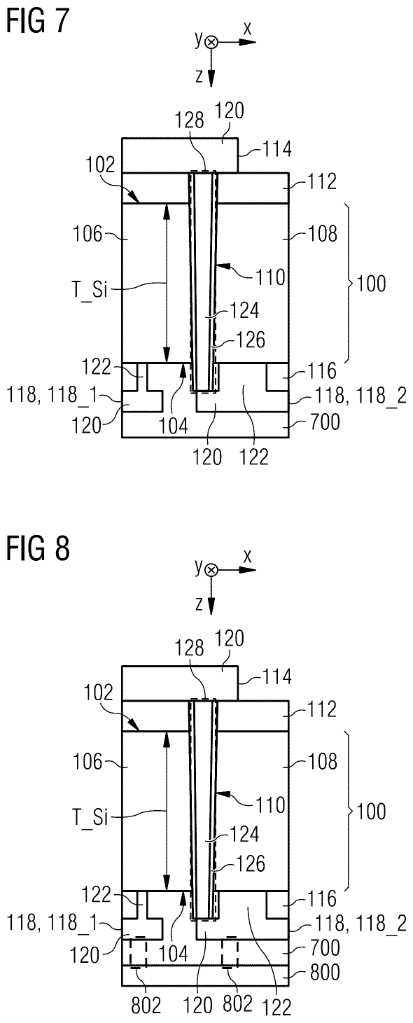

FIGS. 6A through 6C illustrate cross-sectional views of part of the semiconductor device during formation of the backside patterned metallization 118, according to an embodiment. In FIG. 6A, openings 600 are etched in the backside insulation layer 116 that expose the backside 104 of the silicon layer 100 and a metal or metal alloy 602 is deposited on the backside insulation layer 116 and in the openings 600 formed therein. In one embodiment, a copper damascene process is used to deposit the metal or metal alloy 602. In FIG. 6B, a resist layer 604 is formed on the metal or metal alloy 602 and the metal or metal alloy 602 is patterned through openings 606 in the resist layer 604, e.g., by etching. FIG. 6C shows the semiconductor device after the resist layer 604 is removed. The patterning process defines the backside patterned metallization 118 with a plurality of separated sections 608, 610, 612.

In another embodiment, the backside patterned metallization 118 is formed by two separate metal deposition processes. The first metal deposition process includes etching and filling each opening 600 in the backside insulation layer 116 to form at least one via 122 that contacts the backside 104 of the silicon layer 100. The second metal deposition process includes depositing and etching a metal or metal alloy on the backside insulation layer 116 and that contacts each via 122, to form the separated sections 608, 610, 612 shown in FIG. 6C.

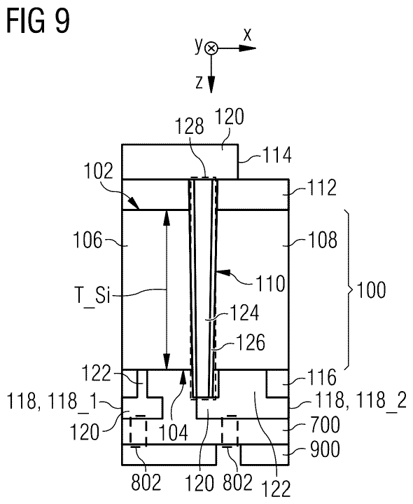

FIG. 7 illustrates a cross-sectional view of part of the semiconductor device, according to an embodiment. In FIG. 7, an additional backside insulation layer 700 is formed on the backside patterned metallization 118 and laterally isolates the sections 118_1, 118_2 of the backside patterned metallization 118 from one another. Any suitable type of dielectric material (e.g., SiO₂, SiN₄, etc.) may be used as the additional backside insulation layer 700. The additional backside insulation layer 700 may provide electrical isolation at the device backside, e.g., to a lead frame or other type of substrate (not shown in FIG. 7).

FIG. 8 illustrates a cross-sectional view of part of the semiconductor device, according to an embodiment. In FIG. 8, a substrate 800 and/or a plurality of contacts 802 are disposed on the additional backside insulation layer 700 and electrically connected to the backside patterned metallization 118. The substrate 800 may be a lead frame, a DBC (direct bonded copper) substrate, an AMB (active metal brazed) substrate, an IMS (insulated metal substrate), metal block, a mold compound, a die attach film, a Si carrier, an adhesive, a circuit board, an interposer, another die (chip), etc. The contacts 802 may be electrically conductive vias, solder bumps, Cu pillars, etc. The additional backside insulation layer 700 can be opened to enable selective contacting between the backside patterned metallization 118 and the substrate 800, e.g., via contacts 802.

FIG. 9 illustrates a cross-sectional view of part of the semiconductor device, according to an embodiment. In FIG. 9, an additional patterned metallization 900 such as a patterned Cu layer is formed on the additional backside insulation layer 700. Providing more than one patterned metallization 118, 900 at the backside 104 of the silicon layer 100 enables more complex routing at the backside 104. Patterned metallizations 114, 118, 900 and insulation layers 112, 116, 700 at both sides 102, 104 of the silicon layer 100 enables chip (die) stacking with two or more chips on top of each other and exchanging information or power vertically to each other and to a substrate 900 such as a lead frame as shown in FIG. 8 and/or to bond contacts 802 also as shown in FIG. 8.

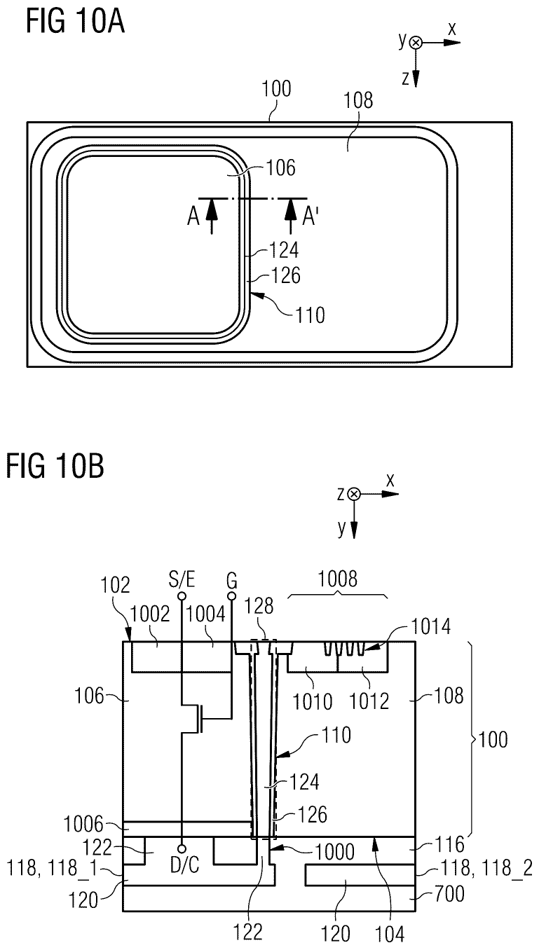

FIG. 10A illustrates a top plan view and FIG. 10B illustrates a corresponding cross-sectional view along the line labelled A-A′ in FIG. 10A of part of the semiconductor device, according to an embodiment. In FIGS. 10A and 10B, a vertical device, which is schematically represented in FIG. 10B using a transistor symbol, is formed in the first device region 106 of the silicon layer 100. The frontside patterned metallization 114 provides a first power terminal connection to the vertical device at the frontside 102 of the silicon layer 100, through at least one opening 132 in the frontside insulation layer 112. The frontside patterned metallization 114 and the frontside insulation layer 112 are not shown in FIGS. 10A and 10B to emphasize other features.

The backside patterned metallization 118 provides a second power terminal connection to the vertical device at the backside 104 of the silicon layer 100, through at least one opening 1000 in the backside insulation layer 116. The second power terminal potential may be input at the device frontside, with a section of the frontside patterned metallization 114 at the second power terminal potential contacting the electrically conductive region 124 of the isolation structure 110 or of the TSV 128 which in turn vertically electrically routes the second power terminal potential to the corresponding section 118_1 of the backside patterned metallization 118. This way, a vertical device such as a power (e.g., 1A or higher) transistor or power diode can be realized without having to externally contact the device backside.

In the case of an IGBT (insulated gate bipolar transistor) as the vertical device, the first power terminal connection provided by the frontside patterned metallization 114 may be the emitter ‘E’ connection and the second power terminal connection provided by the backside patterned metallization 118 may be the collector ‘C’ connection. In the case of a vertical power MOSFET (metal-oxide-semiconductor field-effect transistor) or vertical JFET (junction field-effect transistor) as the vertical device, the first power terminal connection provided by the frontside patterned metallization 114 may be the source ‘S’ connection and the second power terminal connection provided by the backside patterned metallization 118 may be the drain ‘D’ connection. In the case of a power diode as the vertical device, the first power terminal connection provided by the frontside patterned metallization 114 is the anode or cathode connection and the second power terminal connection provided by the backside patterned metallization 118 is the other one of the anode or cathode connection.

FIG. 10B generically shows a source (or emitter) region 1002 and a body region 1004 formed in the first device region 106 at the frontside 102 of the silicon layer 100, and a drain (or collector) region 1006 formed in the first device region 106 at the backside 102 of the silicon layer 100. In the case of a vertical power diode, the body region 1004 would correspond to the anode region and the drain/collector region 1006 would correspond to the cathode region with the source region 1002 being omitted. Still other types of vertical and/or lateral devices may be formed in the first device region 106.

In one embodiment, the vertical device formed in the first device region 106 of the silicon layer 100 is a vertical power transistor device such as an IGBT, power MOSFET, JFET, etc. and a lateral gate driver 1008 is formed in the second device region 108 at the frontside 102 of the silicon layer 100. The lateral gate driver 1008 is generically represented in FIG. 10B by various doped regions 1010, 1012 and gate trenches 1014. The frontside patterned metallization 114 electrically connects the lateral gate driver 1008 formed in the second device region 108 to a gate terminal ‘G’ of the vertical power transistor device formed in the first device region 106.

In another embodiment, the vertical device formed in the first device region 106 of the silicon layer 100 is a light-emitting diode (LED) device and the lateral driver 1008 formed in the second device region 108 at the frontside 102 of the silicon layer 100 is configured to drive the LED. The frontside patterned metallization 114 electrically connects the lateral driver 1008 to the LED device. For an LED, the silicon layer 100 may include 2 to 6 or more semiconductor sublayers with epitaxial superstructures and a one-sided routing may be provided with transparent electrodes such as conductive oxides or transparent metal films.

More generally, the configuration illustrated in FIGS. 10A and 10B enables cointegration of vertical devices, e.g., such as FETs or IGBTs with full routing at the frontside 102. Such cointegration enables formation of various circuit types such as a monolithic half-bridge, a 3-phase or LED driver with vertical power devices, etc.

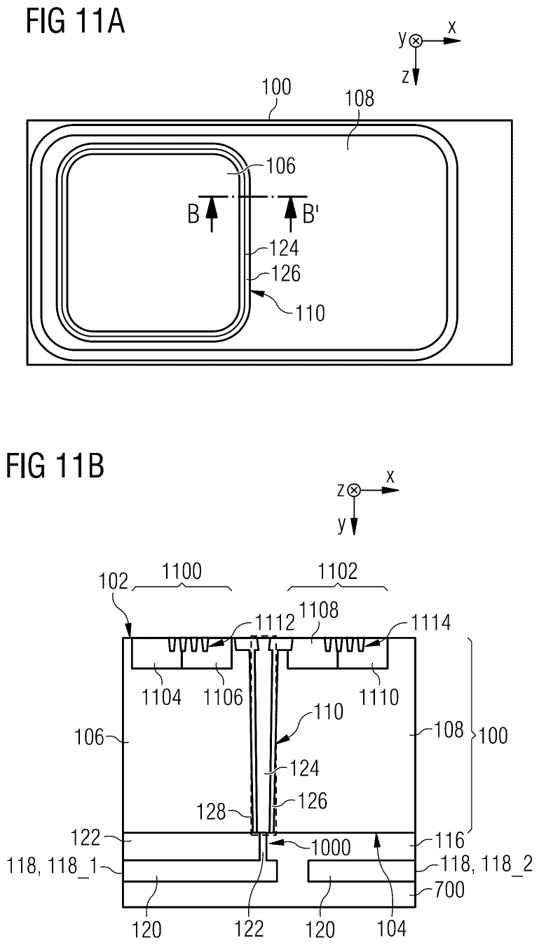

FIG. 11A illustrates a top plan view and FIG. 11B illustrates a corresponding cross-sectional view along the line labelled B-B′ in FIG. 11A of part of the semiconductor device, according to an embodiment. In FIGS. 11A and 11B, the backside patterned metallization 118 applies a bias voltage to the first device region 106 at the backside 104 of the silicon layer 100. For example, the frontside patterned metallization 114 may couple the bias voltage to the backside patterned metallization 118 through the electrically conductive region 124 of the isolation structure 100 or through a TSV 128.

In one embodiment, a first device 1100 is formed in the first device region 106 of the silicon layer 100, a second device 1102 is formed in the second device region 108 of the silicon layer 100, and the frontside patterned metallization 114 electrically interconnects the first device 1100 and the second device 1102 to form a cascode device. The first and second devices 1100, 1102 are generically represented in FIG. 11B by respective doped regions 1104, 1106, 1108, 1110 and gate trenches 1112, 1114. The frontside patterned metallization 114 and the frontside insulation layer 112 are not shown in FIGS. 11A and 11B to emphasize other features.

The first device 1100 and the second device 1102 may have the same rated breakdown voltage. In this example, the first device 1100 and the second device 1102 individually block half the voltage across the cascode device in a blocking state of the cascode device. For example, the second device region 108 may include a high voltage (e.g., 20V or higher) device 1102 with a 500V maximum voltage rating and 0V applied as a backside voltage. Including the same type of device 1100 into the first device region 106 and biassing the reference and backside to 500V enables a stacking of both devices 1100, 1102 with a switching capability of 1000V, with the second device 1102 in the second device region 108 operating between 0V and 500V the first device 1100 in the first device region 106 operating between 500V and 1000V.

Other types of lateral device configurations may be implemented using the laterally isolated device regions 106, 108. For example, two or more lateral devices such as lateral power or high voltage devices such LDMOS devices may be formed in isolated regions 106, 108 within the silicon layer 100 and be connected in series by the frontside patterned metallization 114, with the backside region of one device electrically connected to the high potential of the previous device by the backside patterned metallization 118. Such a configuration enables the devices to have the same back bias, and the devices may be logically stacked as much as the isolation structure 110 permits.

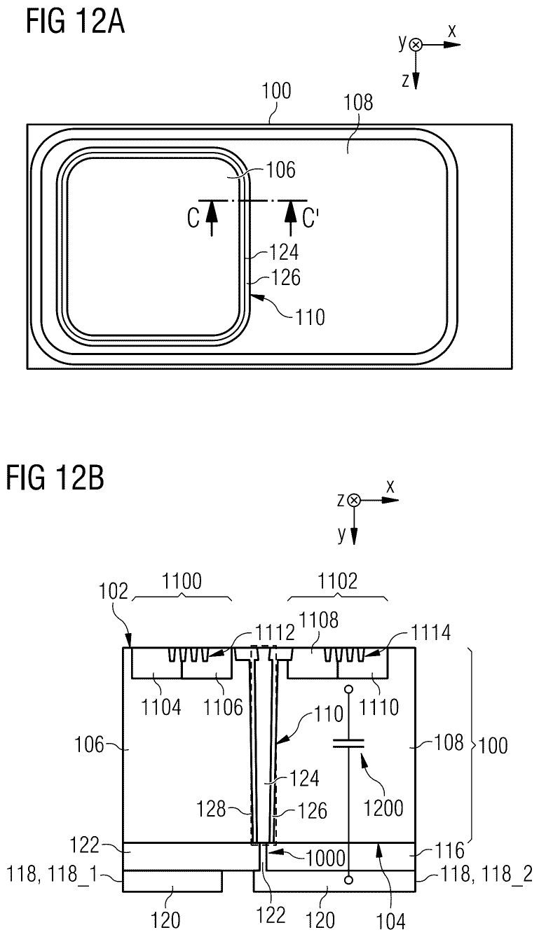

FIG. 12A illustrates a top plan view and FIG. 12B illustrates a corresponding cross-sectional view along the line labelled C-C′ in FIG. 12A of part of the semiconductor device, according to an embodiment. In FIGS. 12A and 12B, the backside patterned metallization 118 includes a section 118_2 capacitively coupled to the second device region 108 at the backside 104 of the silicon layer 100. Separately or in combination, the backside patterned metallization 118 may include another section 118_1 capacitively coupled to the first device region 106 at the backside 104 of the silicon layer 100. The capacitive coupling is schematically indicated by a capacitor 1200 in FIG. 12B.

In FIG. 12B, the electrically conductive region 124 of the isolation structure 110 or of the TSV 128 vertically electrically routes a potential of the backside patterned metallization section 118_2 that is capacitively coupled to the second device region 108 at the backside 104 of the silicon layer 100 to the frontside patterned metallization 114. The capacitive coupling from the frontside 102 to the backside 104 of the silicon layer 100 enables transmission of information via the backside 104 and enables capacitive or leakage sensing for in-situ detection of dielectric failure of the backside insulation layer 116.

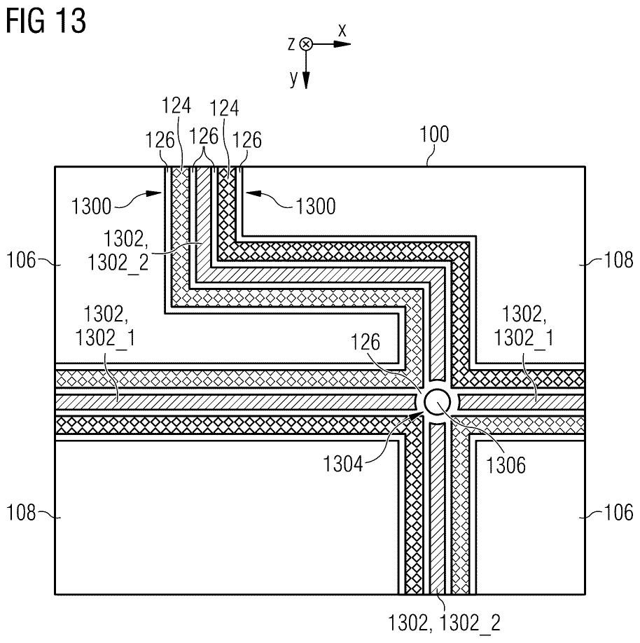

FIG. 13 illustrates a partial top plan view of the silicon layer 100, according to another embodiment. In FIG. 13, the isolation structure 110 includes two or more trenches 1300 extending through the silicon layer 100 from the frontside 102 to the backside 104 (z direction in FIG. 13) and laterally isolating the first device region 106 and the second device region 108 from one another. An electrically conductive material 124 is in the trenches 1300 and a dielectric material 126 separates the electrically conductive material 124 from silicon material of the silicon layer 100. A silicon mesa 1302 is disposed between adjacent ones of the trenches 1300. The electrically conductive material 124 in the trenches 1300 may provide vertical electrical routing between the frontside patterned metallization 114 and the backside patterned metallization 118, e.g., as previously described herein.

In FIG. 13, a first silicon mesa 1300_2 is disposed between (delimited by) adjacent ones of the trenches 1300 in a first lateral direction (x direction in FIG. 13) and a second silicon mesa 1302_2 is disposed between (delimited by) adjacent ones of the trenches 1300 in a second lateral direction (y direction in FIG. 13) that is transverse to the first lateral direction. The first and second silicon mesas 1302_1, 1302_2 intersect one another.

In an area 1304 where the first and second silicon mesas 1302_1, 1302_2 intersect one another, a silicon plug 1306 laterally surrounded by the trench dielectric material 126 interrupts the silicon mesa 1300 where two or more trenches 1300 intersect one another. The silicon plug 1306 instead may interrupt the electrically conductive material 124 where two or more trenches 1300 intersect one another. In yet another embodiment, a first silicon plug 1306 surrounded by the trench dielectric material 126 may interrupt the silicon mesa 1300 and a second silicon plug 1306 surrounded by the trench dielectric material 126 may interrupt the electrically conductive material 124 where two or more trenches 1300 intersect one another. In each of these cases, deep isolated mesa crossings 1304 enable different voltage domains to be placed next to each other without sacrificing die (chip) area.

In one embodiment, the first device regions 106 of the silicon layer 100 shown in FIG. 13 support a first voltage domain and the second device regions 108 of the silicon layer 100 shown in FIG. 13 support a second voltage domain different than the first voltage domain. In the corner area 1304 where one or more of the laterally isolated regions 106 of the first voltage domain adjoin one or more of the laterally isolated regions 108 of the second voltage domain, the silicon plug 1306 separates the first and second silicon mesas 1302_1, 1302_2 from one another.

The silicon plug 1306 may be defined by masking during the trench etching process and a local CD reduction of the mask (not shown) used to etch the trenches 1300 into the silicon layer 100 may be used in areas 1304 where the first and second silicon mesas 1302_1, 1302_2 intersect one another such that the trench dielectric material 126 is thicker in the areas 1304 of reduced CD compared to the regions of the trenches 1300 which include the electrically conductive material 124.

In a lateral direction (x or y direction in FIG. 13), the average thickness of the trench dielectric material 126 around the silicon plug 1306 may be greater than the average thickness of the trench dielectric material 126 between the silicon material of the respective mesa 1302_1, 1302_2 and the electrically conductive material 124 in the adjoining trench 1300. According to this embodiment, the silicon plug 1306 is positioned within a mesa crossing 1304 to yield a CD reduction and thus thicker dielectric material 126 at the mesa crossing 1304.

Although the present disclosure is not so limited, the following numbered examples demonstrate one or more aspects of the disclosure.

Example 1. A semiconductor device, comprising: a silicon layer having a thickness in a range of 2 μm to 200 μm between a frontside and a backside of the silicon layer; a first device region and a second device region laterally isolated from one another in the silicon layer by an isolation structure that extends from the frontside to the backside of the silicon layer; a first insulation layer on the frontside of the silicon layer; a first patterned metallization on the first insulation layer; a second insulation layer on the backside of the silicon layer; and a second patterned metallization on the second insulation layer, wherein the first patterned metallization provides lateral electrical routing along the frontside of the silicon layer, wherein the second patterned metallization provides lateral electrical routing along the backside of the silicon layer.

Example 2. The semiconductor device of example 1, wherein the second patterned metallization contacts the silicon layer at the backside through a plurality of openings in the second insulation layer.

Example 3. The semiconductor device of example 2, wherein the silicon layer comprises a doped contact region adjoining each part of the second patterned metallization that contacts the silicon layer at the backside, and wherein each doped contact region has a higher doping concentration than material of the silicon layer that adjoins the doped contact region.

Example 4. The semiconductor device of any of examples 1 through 3, wherein the second patterned metallization comprises a first section that contacts the silicon layer at the backside through a first opening in the second insulation layer and a second section that contacts an electrically conductive region of the isolation structure or of a through-silicon via that extends through the silicon layer through a second opening in the second insulation layer.

Example 5. The semiconductor device of example 4, wherein the first patterned metallization contacts the electrically conductive region of the isolation structure or of the through-silicon via through an opening in the first insulation layer.

Example 6. The semiconductor device of any of examples 1 through 5, wherein a vertical device is formed in the first device region, wherein the first patterned metallization provides a first power terminal connection to the vertical device at the frontside of the silicon layer, through at least one opening in the first insulation layer, and wherein the second patterned metallization provides a second power terminal connection to the vertical device at the backside of the silicon layer, through at least one opening in the second insulation layer.

Example 7. The semiconductor device of example 6, wherein the vertical device is a vertical power transistor device, wherein a lateral gate driver is formed in the second device region, and wherein the first patterned metallization electrically connects the lateral gate driver to a gate terminal of the vertical power transistor device.

Example 8. The semiconductor device of example 6, wherein the vertical device is a light-emitting diode (LED) device, wherein a lateral driver is formed in the second device region, and wherein the first patterned metallization electrically connects the lateral driver to the LED device.

Example 9. The semiconductor device of any of examples 1 through 8, wherein the second patterned metallization applies a bias voltage to the first device region at the backside of the silicon layer.

Example 10. The semiconductor device of example 9, wherein a first device is formed in the first device region and a second device is formed in the second device region, and wherein the first patterned metallization electrically interconnects the first device and the second device to form a cascode device.

Example 11. The semiconductor device of example 10, wherein the first device and the second device have a same rated breakdown voltage, and wherein in a blocking state of the cascode device, the first device and the second device individually block half the voltage across the cascode device.

Example 12. The semiconductor device of any of examples 9 through 11, wherein the first patterned metallization couples the bias voltage to the second patterned metallization through an electrically conductive region of the isolation structure or through a through-silicon via that extends through the silicon layer.

Example 13. The semiconductor device of any of examples 1 through 12, wherein the second patterned metallization comprises a section capacitively coupled to the first device region or the second device region at the backside of the silicon layer.

Example 14. The semiconductor device of any of examples 1 through 13, wherein the isolation structure provides vertical electrical routing between the first patterned metallization and the second patterned metallization.

Example 15. The semiconductor device of example 14, wherein the isolation structure comprises an electrically conductive material laterally separated from the silicon layer by a dielectric material and/or a pn junction, and wherein the electrically conductive material provides the vertical electrical routing between the first patterned metallization and the second patterned metallization.

Example 16. The semiconductor device of any of examples 1 through 14, further comprising a through silicon via that extends through the silicon layer and provides vertical electrical routing between the first patterned metallization and the second patterned metallization.

Example 17. The semiconductor device of any of examples 1 through 16, wherein the isolation structure comprises: a plurality of trenches extending through the silicon layer from the frontside to the backside and laterally isolating the first device region and the second device region from one another; an electrically conductive material in the trenches; a dielectric material separating the electrically conductive material from silicon material of the silicon layer; and a silicon mesa between adjacent ones of the trenches, wherein the electrically conductive material in the trenches provides the vertical electrical routing between the first patterned metallization and the second patterned metallization.

Example 18. The semiconductor device of example 17, wherein the isolation structure further comprises a silicon plug laterally surrounded by the dielectric material and interrupting the silicon mesa where two or more trenches intersect one another.

Example 19. The semiconductor device of any of examples 1 through 18, further comprising: a third insulation layer on the second patterned metallization, wherein the third insulation layer laterally isolates sections of the second patterned metallization from one another.

Example 20. The semiconductor device of example 19, further comprising: a substrate or a plurality of contacts on the third insulation layer and electrically connected to the second patterned metallization.

Example 21. The semiconductor device of example 19, further comprising: a third patterned metallization on the third insulation layer.

Example 22. A method of producing a semiconductor device, the method comprising: forming a silicon layer having a thickness in a range of 2 μm to 200 μm between a frontside and a backside of the silicon layer; forming a first device region and a second device region that are laterally isolated from one another in the silicon layer by an isolation structure that extends from the frontside to the backside of the silicon layer; forming a first insulation layer on the frontside of the silicon layer; forming a first patterned metallization on the first insulation layer; forming a second insulation layer on the backside of the silicon layer; and forming a second patterned metallization on the second insulation layer, wherein the first patterned metallization provides lateral electrical routing along the frontside of the silicon layer, wherein the second patterned metallization provides lateral electrical routing along the backside of the silicon layer.

Example 23. The method of example 22, further comprising: after the silicon layer is formed to have a thickness in the range of 10 μm to 200 μm but before forming both the second insulation layer and the second patterned metallization, blanket implanting a dopant species into the backside of the silicon layer.

Example 24. The method of example 23, further comprising: after the silicon layer is formed to have a thickness in the range of 10 μm to 200 μm but before forming both the second insulation layer and the second patterned metallization, forming a resist layer on the backside of the silicon layer and implanting a dopant species into the backside of the silicon layer through openings in the resist layer.

Example 25. The method of any of examples 22 through 24, further comprising: after the silicon layer is formed to have a thickness in the range of 10 μm to 200 μm but before forming the second patterned metallization, forming a resist layer on the second insulation layer and implanting a dopant species into the backside of the silicon layer through openings in the resist layer and the second insulation layer.

Example 26. The method of any of examples 22 through 25, wherein forming the second patterned metallization comprises: etching a plurality of openings in the second insulation layer and that expose the backside of the silicon layer; depositing a metal or metal alloy on the second insulation layer and in the plurality of openings; forming a resist layer on the metal or metal alloy; and patterning the metal or metal alloy through openings in the resist layer.

Example 27. The method of any of examples 22 through 25, wherein forming the second patterned metallization comprises: etching and filling an opening in the second insulation layer to form a via that contacts the backside of the silicon layer; and depositing and etching a metal or metal alloy on the second insulation layer and that contacts the via.

Example 28. The method of any of examples 22 through 27, further comprising: forming a third insulation layer on the second patterned metallization, wherein the third insulation layer laterally isolates sections of the second patterned metallization from one another.

Example 29. The method of any of examples 22 through 28, wherein the isolation structure provides vertical electrical routing between the first patterned metallization and the second patterned metallization.

Example 30. The method of any of examples 22 through 29, further comprising: forming a through silicon via that extends through the silicon layer and provides vertical electrical routing between the first patterned metallization and the second patterned metallization.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a silicon layer having a thickness in a range of 2 μm to 200 μm between a frontside and a backside of the silicon layer;
a first device region and a second device region laterally isolated from one another in the silicon layer by an isolation structure that extends from the frontside to the backside of the silicon layer;
a first insulation layer on the frontside of the silicon layer;
a first patterned metallization on the first insulation layer;
a second insulation layer on the backside of the silicon layer; and
a second patterned metallization on the second insulation layer,
wherein the first patterned metallization provides lateral electrical routing along the frontside of the silicon layer,
wherein the second patterned metallization provides lateral electrical routing along the backside of the silicon layer.

2. The semiconductor device of claim 1, wherein the second patterned metallization contacts the silicon layer at the backside through a plurality of openings in the second insulation layer.

3. The semiconductor device of claim 2, wherein the silicon layer comprises a doped contact region adjoining each part of the second patterned metallization that contacts the silicon layer at the backside, and wherein each doped contact region has a higher doping concentration than material of the silicon layer that adjoins the doped contact region.

4. The semiconductor device of claim 1, wherein the second patterned metallization comprises:
a first section that contacts the silicon layer at the backside through a first opening in the second insulation layer; and
a second section that contacts an electrically conductive region of the isolation structure or of a through-silicon via that extends through the silicon layer through a second opening in the second insulation layer.

5. The semiconductor device of claim 4, wherein the first patterned metallization contacts the electrically conductive region of the isolation structure or of the through-silicon via through an opening in the first insulation layer.

6. The semiconductor device of claim 1, wherein a vertical device is formed in the first device region, wherein the first patterned metallization provides a first power terminal connection to the vertical device at the frontside of the silicon layer, through at least one opening in the first insulation layer, and wherein the second patterned metallization provides a second power terminal connection to the vertical device at the backside of the silicon layer, through at least one opening in the second insulation layer.

7. The semiconductor device of claim 6, wherein the vertical device is a vertical power transistor device, wherein a lateral gate driver is formed in the second device region, and wherein the first patterned metallization electrically connects the lateral gate driver to a gate terminal of the vertical power transistor device.

8. The semiconductor device of claim 6, wherein the vertical device is a light-emitting diode (LED) device, wherein a lateral driver is formed in the second device region, and wherein the first patterned metallization electrically connects the lateral driver to the LED device.

9. The semiconductor device of claim 1, wherein the second patterned metallization applies a bias voltage to the first device region at the backside of the silicon layer.

10. The semiconductor device of claim 9, wherein a first device is formed in the first device region and a second device is formed in the second device region, and wherein the first patterned metallization electrically interconnects the first device and the second device to form a cascode device.

11. The semiconductor device of claim 10, wherein the first device and the second device have a same rated breakdown voltage, and wherein in a blocking state of the cascode device, the first device and the second device individually block half the voltage across the cascode device.

12. The semiconductor device of claim 9, wherein the first patterned metallization couples the bias voltage to the second patterned metallization through an electrically conductive region of the isolation structure or through a through-silicon via that extends through the silicon layer.

13. The semiconductor device of claim 1, wherein the second patterned metallization comprises a section capacitively coupled to the first device region or the second device region at the backside of the silicon layer.

14. The semiconductor device of claim 1, wherein the isolation structure provides vertical electrical routing between the first patterned metallization and the second patterned metallization.

15. The semiconductor device of claim 14, wherein the isolation structure comprises an electrically conductive material laterally separated from the silicon layer by a dielectric material and/or a pn junction, and wherein the electrically conductive material provides the vertical electrical routing between the first patterned metallization and the second patterned metallization.

16. The semiconductor device of claim 1, further comprising a through silicon via that extends through the silicon layer and provides vertical electrical routing between the first patterned metallization and the second patterned metallization.

17. The semiconductor device of claim 1, wherein the isolation structure comprises:
a plurality of trenches extending through the silicon layer from the frontside to the backside and laterally isolating the first device region and the second device region from one another;
an electrically conductive material in the trenches;
a dielectric material separating the electrically conductive material from silicon material of the silicon layer; and
a silicon mesa between adjacent ones of the trenches,
wherein the electrically conductive material in the trenches provides the vertical electrical routing between the first patterned metallization and the second patterned metallization.

18. The semiconductor device of claim 17, wherein the isolation structure further comprises a silicon plug laterally surrounded by the dielectric material and interrupting the silicon mesa where two or more trenches intersect one another.

19. The semiconductor device of claim 1, further comprising:
a third insulation layer on the second patterned metallization,
wherein the third insulation layer laterally isolates sections of the second patterned metallization from one another.

20. The semiconductor device of claim 19, further comprising:
a substrate or a plurality of contacts on the third insulation layer and electrically connected to the second patterned metallization.

21. The semiconductor device of claim 19, further comprising:
a third patterned metallization on the third insulation layer.

22. A method of producing a semiconductor device, the method comprising:
forming a silicon layer having a thickness in a range of 2 μm to 200 μm between a frontside and a backside of the silicon layer;
forming a first device region and a second device region that are laterally isolated from one another in the silicon layer by an isolation structure that extends from the frontside to the backside of the silicon layer;
forming a first insulation layer on the frontside of the silicon layer;
forming a first patterned metallization on the first insulation layer;
forming a second insulation layer on the backside of the silicon layer; and
forming a second patterned metallization on the second insulation layer,
wherein the first patterned metallization provides lateral electrical routing along the frontside of the silicon layer,
wherein the second patterned metallization provides lateral electrical routing along the backside of the silicon layer.

23. The method of claim 22, further comprising:
after the silicon layer is formed to have a thickness in the range of 10 μm to 200 μm but before forming both the second insulation layer and the second patterned metallization, blanket implanting a dopant species into the backside of the silicon layer.

24. The method of claim 23, further comprising:
after the silicon layer is formed to have a thickness in the range of 10 μm to 200 μm but before forming both the second insulation layer and the second patterned metallization, forming a resist layer on the backside of the silicon layer and implanting a dopant species into the backside of the silicon layer through openings in the resist layer.

25. The method of claim 22, further comprising:
after the silicon layer is formed to have a thickness in the range of 10 μm to 200 μm but before forming the second patterned metallization, forming a resist layer on the second insulation layer and implanting a dopant species into the backside of the silicon layer through openings in the resist layer and the second insulation layer.

26. The method of claim 22, wherein forming the second patterned metallization comprises:
etching a plurality of openings in the second insulation layer and that expose the backside of the silicon layer;
depositing a metal or metal alloy on the second insulation layer and in the plurality of openings;
forming a resist layer on the metal or metal alloy; and
patterning the metal or metal alloy through openings in the resist layer.

27. The method of claim 22, wherein forming the second patterned metallization comprises:
etching and filling an opening in the second insulation layer to form a via that contacts the backside of the silicon layer; and
depositing and etching a metal or metal alloy on the second insulation layer and that contacts the via.

28. The method of claim 22, further comprising:
forming a third insulation layer on the second patterned metallization,
wherein the third insulation layer laterally isolates sections of the second patterned metallization from one another.

29. The method of claim 22, wherein the isolation structure provides vertical electrical routing between the first patterned metallization and the second patterned metallization.

30. The method of claim 22, further comprising:
forming a through silicon via that extends through the silicon layer and provides vertical electrical routing between the first patterned metallization and the second patterned metallization.
